(19) United States
(12) Patent Application Publication
(10) Pub. No.: US 2025/0008732 A1
(43) Pub. Date: Jan. 2, 2025

(54) MEMORY DEVICE AND MANUFACTURING METHOD OF THE MEMORY DEVICE

(71) Applicant: SK hynix Inc., Icheon-si Gyeonggi-do (KR)

(72) Inventors: Hyung Jun YANG, Icheon-si Gyeonggi-do (KR); Tae Soo JUNG, Icheon-si Gyeonggi-do (KR)

(73) Assignee: SK hynix Inc., Icheon-si Gyeonggi-do (KR)

(21) Appl. No.: 18/521,549

(22) Filed: Nov. 28, 2023

(30) Foreign Application Priority Data
Jun. 29, 2023 (KR) 10-2023-0084014

(51) Int. Cl. H10B 43/27

(52) U.S. Cl. CPC H10B 43/27

(57) ABSTRACT

A memory device may include a stack structure, comprised of layers of first and second materials, which are alternately stacked. The stack structure also include a channel layer inside the stack structure. The channel layer may include a first sub-channel layer, a liner layer formed along an inner wall of the first sub-channel layer, and a second sub-channel layer formed along an inner wall of the liner layer.

### CROSS-REFERENCE TO RELATED APPLICATION

The present application claims priority under 35 U.S.C. § 119(a) to Korean patent application number 10-2023-0084014 filed on Jun. 29, 2023, in the Korean Intellectual Property Office, the entire disclosure of which is incorporated by reference herein.

### BACKGROUND

### 1. Technical Field

The present disclosure generally relates to a memory device and a manufacturing method of the memory device, and more particularly, to a memory device including a cell plug extending in a vertical direction and a manufacturing method of the memory device.

### 2. Related Art

A memory device may include a nonvolatile memory device in which stored data is retained as it is even when power supply is interrupted. The nonvolatile memory device may be divided into a two-dimensional structure and a three-dimensional structure according to a structure in which memory cells are arranged. Memory cells of a nonvolatile memory device having a two-dimensional structure may be arranged in a single layer above a substrate, and memory cells of a non-volatile memory device having a three-dimensional structure may be stacked in a vertical direction above a substrate. Since a degree of integration of the nonvolatile memory device having the three-dimensional structure is higher than a degree of integration of the nonvolatile memory device having the two-dimensional structure, electronic devices using the nonvolatile memory device having the three-dimensional structure have recently been increasingly used.

### SUMMARY

Embodiments provide a memory device and a manufacturing method of the memory device, which can improve the operational reliability of the memory device.

In accordance with an aspect of the present disclosure, there is provided a memory device including: a stack structure; and a channel layer inside the stack structure, wherein the channel layer includes: a first sub-channel layer; a liner layer formed along an inner wall of the first sub-channel layer; and a second sub-channel layer formed along an inner wall of the liner layer.

In accordance with another aspect of the present disclosure, there is provided a method of manufacturing a memory device, the method including: forming a stack structure in which first material layers and second material layers are alternately stacked; forming an opening inside the stack structure; forming a first sub-channel layer in the opening; forming a liner layer along an inner wall of the first sub-channel layer; and forming a second sub-channel layer along an inner wall of the liner layer.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a block diagram illustrating functional elements of a memory device in accordance with an embodiment of the present disclosure.

FIG. 2 is a circuit diagram illustrating components included in a memory device in accordance with an embodiment of the present disclosure.

FIGS. 3A and 3B are vertical cross-sectional views illustrating a structure of a memory device in accordance with an embodiment of the present disclosure.

FIGS. 4A to 4H are views illustrating steps of a manufacturing method of a memory device in accordance with an embodiment of the present disclosure. FIGS. 4A to 4H also illustrate features recited in the claims, including inside and outside walls of memory device components depicted in FIG. 3A and 3B, said walls being described below as shown in FIGS. 3A and 3B.

FIGS. 5A and 5B are vertical cross-sectional views illustrating a section of a memory device including a cell plug in accordance with an embodiment of the present disclosure.

FIG. 6 is a diagram illustrating a memory card system to which the memory device of the present disclosure is applied.

FIG. 7 is a diagram illustrating a Solid State Drive (SSD) system to which the memory device of the present disclosure is applied.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms, and cannot be construed as limited to the embodiments set forth herein.

Hereinafter, exemplary embodiments of the present disclosure will be described in detail with reference to the accompanying drawings in order for those skilled in the art to be able to readily implement the technical spirit of the present disclosure.

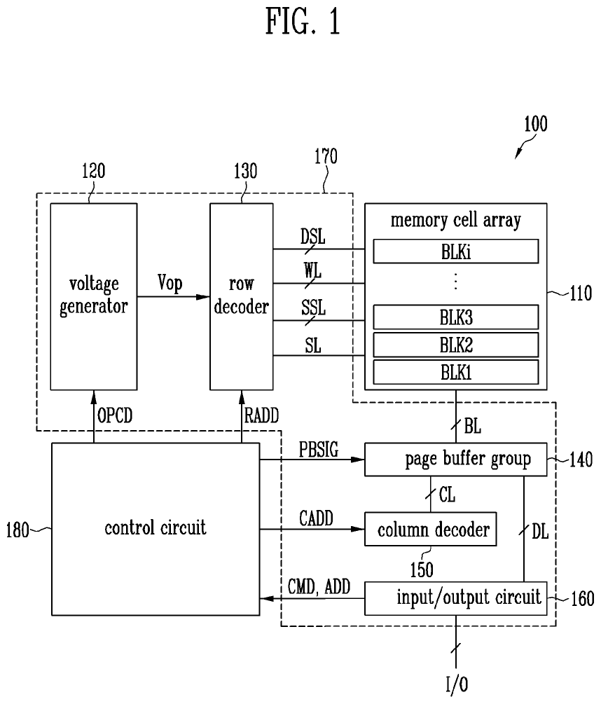

FIG. 1 is a diagram illustrating a memory device in accordance with an embodiment of the present disclosure.

Referring to FIG. 1, the memory device 100 may include a memory cell array 110, a peripheral circuit 170, and a control circuit 180.

The memory cell array 110 may include first to ith memory blocks BLK1 to BLKi. Each of the first to ith memory blocks BLK1 to BLKi may include memory cells capable of storing data. Drain select lines DSL, word lines WL, source select lines SSL, and a source line SL may be connected to each of the first to ith memory blocks BLK1 to BLKi, and bit lines BL may be commonly connected to the first to ith memory blocks BLK1 to BLKi.

The first to ith memory blocks BLK1 to BLKi may be formed in a three-dimensional structure. The memory blocks having the three-dimensional structure may include memory cells stacked in a vertical direction above a substrate.

The memory cells may store one-bit or two-or-more-bit data according to a program manner. For example, a manner in which one-bit data is stored in one memory cell is referred to as a single level cell (SLC) manner, and a manner in which two-bit data is stored in one memory cells is referred to as a multi-level cell (MLC) manner. A manner in which three-bit data is stored in one memory cell is referred to as a triple level cell (TLC) manner, and a manner in which four-bit data is stored in one memory cell is referred to as a quad level cell (QLC) manner. In addition, five-or-more-bit data May be stored in one memory cell.

The peripheral circuit 170 may be configured to perform a program operation for storing data, a read operation for outputting data stored in the memory cell array 110, and an erase operation for erasing data stored in the memory cell array 110. For example, the peripheral circuit 170 may include a voltage generator 120, a row decoder 130, a page buffer group 140, a column decoder 150, and an input/output circuit 160.

The voltage generator 120 may generate various operating voltages Vop used for a program operation, a read operation, or an erase operation in response to an operation code OPCD. For example, the voltage generator 120 is configured to generate program voltages, turn-on voltages, turn-off voltages, negative voltages, precharge voltages, verify voltages, read voltages, pass voltages, or erase voltages in response to the operation code OPCD. The operating voltages Vop generated by the voltage generator 120 may be applied to drain select lines DSL, word lines WL, source select lines SSL, and a source line SL of a selected memory block through the row decoder 130.

The program voltages are voltages applied to a selected word line among word lines WL in a program operation, and may be used to increase a threshold voltage of memory cells connected to the selected word line. The turn-on voltages may be applied to the drain select lines DSL or the source select lines SSL, and be used to turn on drain select transistors or source select transistors. The turn-off voltages may be applied to the drain select lines DSL or the source select lines SSL, and be used to turn off the drain select transistors or the source select transistors. For example, the turn-off voltage may be set to 0V. The precharge voltages are voltages higher than 0V, and may be applied to the bit lines in a read operation. The verify voltages may be used in a verify operation for determining whether a threshold voltage of selected memory cells has been increased to a target level. The verify voltages may be set to various levels according to the target level, and be applied to a selected word line.

The read voltages may be applied to a selected word line in a read operation of selected memory cells. For example, the read voltages may be set to various levels according to a program manner of the selected memory cells. The pass voltages are voltages applied to unselected word lines among the word lines WL in a program or read operation, and may be used to turn on memory cells connected to the unselected word lines. The erase voltages may be used in an erase operation for erasing memory cells included in a selected memory block, and be applied to the source line SL.

The row decoder 130 may be configured to transmit the operating voltages Vop to drain select lines DSL, word lines WL, source select lines SSL, and a source line SL, which are connected to a selected memory block, according to a row address RADD. For example, the row decoder 130 may be connected to the voltage generator 120 through global lines, and may be connected to the first to ith memory blocks BLK1 to BLKi through the drain select lines DSL, the word lines WL, the source select lines SSL, and the source line SL.

The page buffer group 140 may include page buffers (not shown) connected to each of the first to ith memory blocks BLK1 to BLKi. The page buffers (not shown) may be connected to the first to ith memory blocks BLK1 to BLKi respectively through the bit lines BL. In a read operation, the page buffers (not shown) may sense a current or a voltage of the bit lines BL, which varies according to threshold voltages of selected memory cells, and temporarily store sensed data, in response to page buffer control signals PBSIG.

The column decoder 150 may be configured to transmit data between the page buffer group 140 and the input/output circuit 160 in response to a column address CADD. For example, the column decoder 150 may be connected to the page buffer group 140 through column lines CL, and transmit enable signals through the column lines. The page buffers (not shown) included in the page buffer group 140 may receive or output data through data lines DL in response to the enable signals.

The input/output circuit 160 may be configured to receive or output a command CMD, an address ADD, or data through input/output lines I/O. For example, the input/output circuit 160 may transmit, to the control circuit 180, a command CMD and an address ADD, which are received from an external controller, through the input/output lines I/O, and transmit data received from the external controller to the page buffer group 140 through the input/output lines I/O. Alternatively, the input/output circuit 160 may output data transferred from the page buffer group 140 to the external controller through the input/output lines I/O.

The control circuit 180 may output at least one of an operation code OPCD, the row address RADD, the page buffer control signals PBSIG, and the column address CADD in response to the command CMD and the address ADD. For example, when the command CMD input to the control circuit 180 is a command corresponding to a program operation, the control circuit 180 may control the peripheral circuit 170 to perform a program operation of a memory block selected by the address ADD. When the command CMD input to the control circuit 180 is a command corresponding to a read operation, the control circuit 180 may control the peripheral circuit 170 to perform the read operation of the selected memory block selected and output read data. When the command CMD input to the control circuit 180 is a command corresponding to an erase operation, the control circuit 180 may control the peripheral circuit 170 to perform the erase operation of the selected memory block.

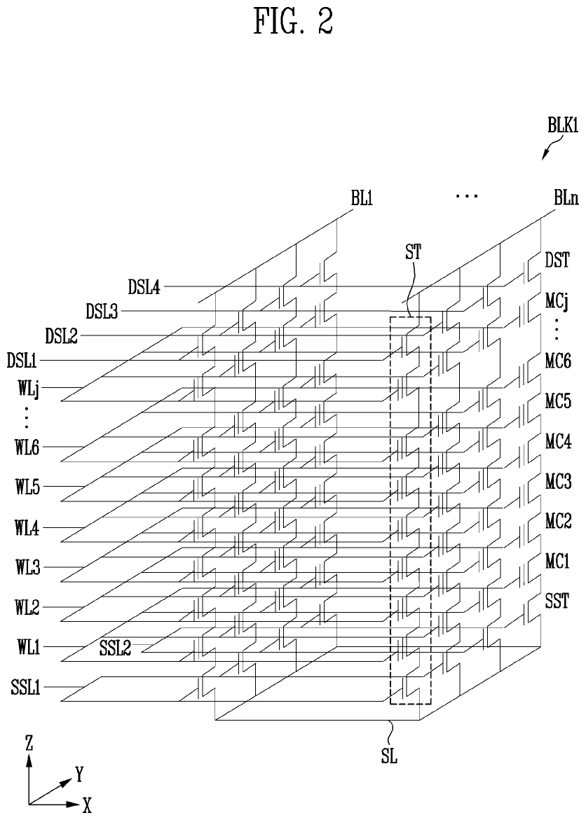

FIG. 2 is a circuit diagram illustrating components included in a memory device in accordance with an embodiment of the present disclosure.

Referring to FIG. 2, a first memory block BLK1 may include strings ST connected between first to nth bit lines BL1 to BLn and a source line SL. The first to nth bit lines BL1 to BLn extend along a Y direction and are arranged to be spaced apart from each other along an X direction. Therefore, the strings ST may also be arranged to be spaced apart from each other along the X and Y directions. For example, strings ST may be connected between the first bit line BL1 and the source line SL, and strings ST may be arranged between the nth bit line BLn and the source line SL. The strings ST may extend along a Z direction.

Any one string ST among strings ST connected to the nth bit line BLn will be described as an example. The string ST may include a source select transistor SST, first to jth memory cells MC1 to MCj, and a drain select transistor DST. The first memory block BLK1 shown in FIG. 2 is a diagram schematically illustrating a structure of a memory block, and therefore, numbers of source select transistors SST, first to jth memory cells MC1 to MCj, and drain select transistors DST, which are included in the strings ST, may vary according to a memory device.

Gates of source select transistors SST included in different strings ST may be connected to a first or second source select line SSL1 or SSL2, gates of first to jth memory cells MC1 to MCj included in the different strings ST may be connected to first to jth word lines WL1 to WLj, and gates of drain select transistors DST included in the different strings ST may be connected to any one of first to fourth drain select lines DSL1 to DSL4.

The lines connected to the first memory block BLK1 will be described in detail. Source select transistors SST arranged along the X direction may be connected to the same source select line, and source select transistors SST arranged along the Y direction may be connected to source select lines isolated from each other. For example, some of the source select transistors SST arranged in the Y direction may be connected to the first source select line SSL1, and the others of the source select transistors SST arranged in the Y direction may be connected to the second source select line SSL2. The second source select line SSL2 may be a line isolated from the first source select line SSL1. Therefore, a voltage applied to the first source select line SSL1 may be equal to or different from a voltage applied to the second source select line SSL2.

Memory cells formed in the same layer among the first to jth memory cells MC1 to MCj may be connected to the same word line. For example, first memory cells MC1 included in different strings ST may be commonly connected to the first word line WL1, and jth memory cells MCj included in the different strings ST may be commonly connected to the jth word line WLj. A group of memory cells which are included in different strings ST and are connected to the same word line may be designated as a page, and a program and read operations may be performed in units of pages.

Drain select transistors DST arranged in the Y direction may be respectively connected to the first to fourth drain select lines DSL1 to DSL4 isolated from each other. Specifically, drain select transistors DST arranged along the X direction may be connected to the same drain select line, and drain select transistors DST arranged along the Y direction may be connected to the first to fourth drain select lines DSL1 to DSL4 isolated from each other. Since the first to fourth drain select lines DSL1 to DSL4 are isolated from each other, different voltages may be applied to the first to fourth drain select lines DSL1 to DSL4.

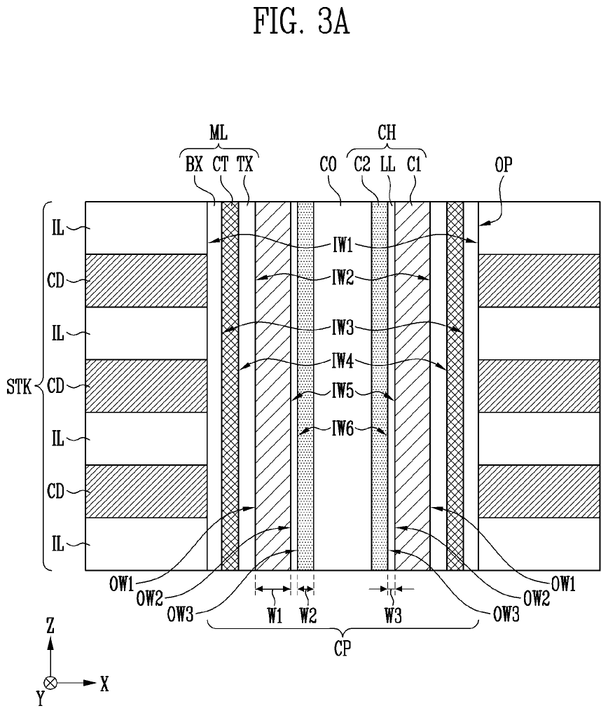

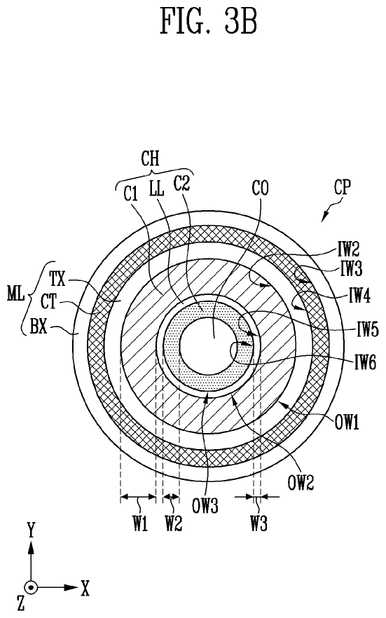

FIGS. 3A and 3B are vertical cross-sectional views illustrating a structure of a memory device in accordance with an embodiment of the present disclosure. FIG. 3A is a vertical cross-sectional view illustrating a section of a cell plug CP in accordance with the present disclosure. FIG. 3B is a plan view illustrating a layout of the cell plug CP in accordance with the present disclosure.

Referring to FIG. 3A, the memory device may include a stack structure STK. The stack structure STK may include conductive layers CD and interlayer insulating layers IL, which are alternately stacked. The conductive layers CD and the interlayer insulating layers IL may be alternately stacked in the Z direction. For example, the stack structure STK may be formed by alternately stacking sacrificial layers and the interlayer insulating layers IL and replacing the sacrificial layers with the conductive layers CD. The conductive layers CD may correspond to the drain select line DSL1, DSL2, DSL3 or DSL4), the first to jth word lines WL1 to WLj, and the source select line SSL1 or SSL2, which are shown in FIG. 2.

The memory device may include a cell plug CP inside the stack structure STK. The cell plug CP may be disposed inside the conductive layers CD and the interlayer insulating layers IL, which are alternately stacked. For example, the stack structure STK may include an opening OP, and the cell plug CP may be formed in the opening OP. The cell plug CP may extend in the Z direction. The cell plug CP may correspond to each of the strings ST shown in FIG. 2. The first to jth memory cells MC1 to MCj shown in FIG. 2 may be respectively formed at places at which the cell plug CP and the conductive layers CD intersect each other.

Referring to FIGS. 3A and 3B, the cell plug CP may include: a memory layer ML formed along an inner wall IW1 of the opening OP; a channel layer CH formed along an inner wall IW2 of the memory layer ML; and a pillar CO inside the channel layer CH. The pillar CO may be formed inside the channel layer CH, and have a cylindrical shape. The memory layer ML may be formed along an outer wall OW1 of the channel layer CH. For example, the memory layer ML may surround an outside surface of the channel layer CH. The channel layer CH may be formed on the inner wall IW2 of the memory layer ML. The inner wall IW2 of the memory layer ML and the outside surface OW1 of the channel layer CH, are in direct contact with each other and are considered herein as “facing” each other.

Each of the memory layer ML, the channel CH, and the pillar CO may extend in the Z direction. Each of the memory layer ML, the channel CH, and the pillar CO may extend through all of the alternately-stacked layers such that the memory layer ML, the channel CH, and the pillar C, penetrate, the stack structure STK or penetrate only a portion of the stack structure STK.

Each of the memory layer ML and the channel layer CH may be formed of at least two different materials. For example, each of the memory layer ML and the channel layer CH may be formed of a triple-layer. The pillar CO may be formed of an insulating layer or a conductive layer.

The memory layer ML may include a blocking layer BX, a charge trap layer CT, or a tunnel insulating layer TX, or include a combination of at least two thereof. The blocking layer BX may be formed along the inner wall IW1 of the opening OP. The charge trap layer CT may be formed along an inner wall IW3 of the blocking layer BX, and the tunnel insulating layer TX may be formed along an inner wall IW4 of the charge trap layer CT. The tunnel insulating layer TX may surround the outside surface OW1 of the channel layer CH. The charge trap layer CT may surround an outside surface of the tunnel insulating layer TX. The blocking layer BX may surround an outside surface of the charge trap layer CT. Each of the blocking layer BX, the charge trap layer CT, and the tunnel insulating layer TX may extend in the Z direction. The blocking layer BX and the tunnel insulating layer TX may be formed of an oxide layer (e.g., a silicon oxide) or an oxynitride layer (e.g., a silicon oxynitride layer), or be formed of any combination thereof. The charge trap layer CT is a charge storage layer, and may include a nitride layer or a variable resistance material.

The channel layer CH may include a first sub-channel layer C1, a liner layer LL, and a second sub-channel layer C2. For example, the first sub-channel layer C1 may be formed along the inner wall IW2 of the memory layer ML (e.g., the tunnel insulating layer TX), the liner layer LL may be formed along an inner wall IW5 of the first sub-channel layer C1, and the second sub-channel layer C2 may be formed along an inner wall IW6 of the liner layer LL. In addition, the liner layer LL may be formed on an outer wall OW3 of the second sub-channel layer C2, and the first sub-channel layer C1 may be formed on an outer wall OW2 of the liner layer LL. For example, the liner layer LL may surround a side surface of the second sub-channel layer C2, and the first sub-channel layer C1 may surround a side surface of the liner layer LL. Each of the first sub-channel layer C1, the second sub-channel layer C2, and the liner layer LL may extend in the Z direction. Each of the first sub-channel layer C1, the second sub-channel layer C2, and the liner layer LL may penetrate the stack structure STK. The first sub-channel layer C1, the second sub-channel layer C2, and the liner layer LL may have cylinder shapes having different diameters.

The first sub-channel layer C1 may include an undoped silicon layer. The undoped silicon layer may be a silicon layer into which any impurity is not doped.

The first sub-channel layer C1 may have a first width W1. The first sub-channel layer C1 may be formed to be thicker than either the liner layer LL or the second sub-channel layer C2. For example, the width of the first sub-channel layer C1 may be within 150 Å.

The second sub-channel layer C2 may include a silicon layer doped with Group III element “impurity,” such as boron, aluminum, gallium, indium or the like. For example, the second sub-channel layer C2 may include a silicon layer doped with boron (B). The second sub-channel layer C2 formed of silicon doped with a Group XIII element (e.g., boron) may include holes as charge carriers.

The second sub-channel layer C2 may have a second width W2 narrower than the first width W1. The second sub-channel layer C2 may be formed thinner than the first sub-channel layer C1 and be formed thicker than the liner layer LL. For example, the width of the second sub-channel layer C2 may be about 20 Å.

The liner layer LL may be an insulating layer. For example, the liner layer LL may be an oxide layer, an oxynitride layer, or an oxide layer doped with a metal. The liner layer LL may isolate the first sub-channel layer C1 and the second sub-channel layer C2 from each other between the first sub-channel layer C1 and the second sub-channel layer C2. The liner layer LL may block or interrupt leakage of the impurity or the charge carriers (e.g., the holes), included in the second sub-channel layer C2, into the first sub-channel layer C1.

The liner layer LL may have a third width W3 narrower than the second width W2. The width of the liner layer LL may be smaller than the width of each of the first and second sub-channel layers C1 and C2. For example, the width of the liner layer LL may be about 10 Å. The liner layer LL may have a thin thickness as compared with the first and second sub-channel layers C1 and C2 such that the first sub-channel layer C1 and the second sub-channel layer C2 are not electrically insulated from each other while being isolated from each other.

In accordance with the present disclosure, when the channel layer CH includes the first sub-channel layer C1, the liner layer LL, and the second sub-channel layer C2, the quantity of charge carriers (e.g., holes) included in the channel layer CH may be large as compared with the existing channel layers not including the liner layer LL. For example, since the liner layer LL is located on the outer wall of the second sub-channel layer C2 doped with the impurity, the concentration of the impurity (e.g., boron) doped into the second sub-channel layer C2 may be increased as compared with the existing channel layers, and accordingly, the channel layer CH may include a large quantity of charge carriers (e.g., holes) as compared with the existing channel layers. Thus, in accordance with the present disclosure, the Virgin Threshold Voltage (VVT) of memory cells (e.g., MC1 to MCj) can be increased, the spreading of charge carriers (e.g., holes) can be reduced, and the reliability (e.g., retention) of the memory device can be improved.

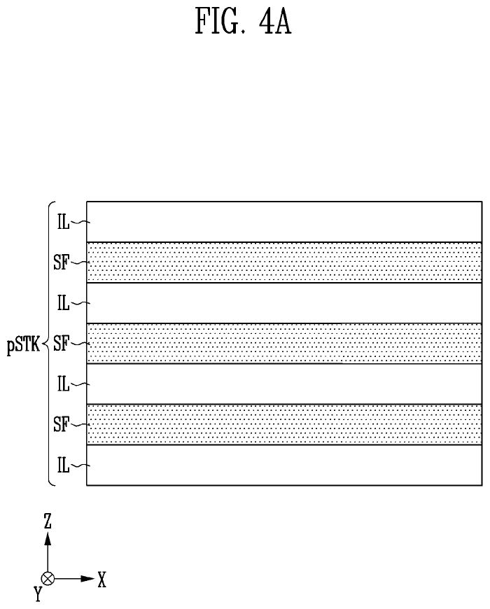

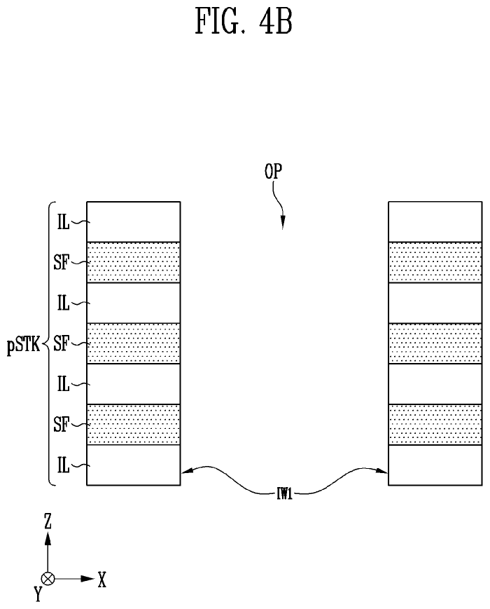

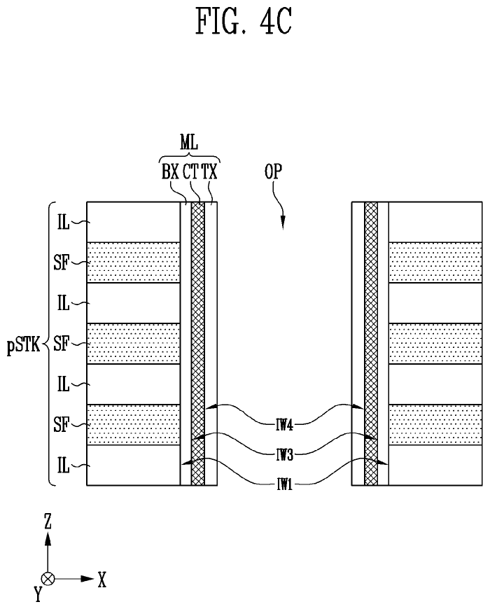

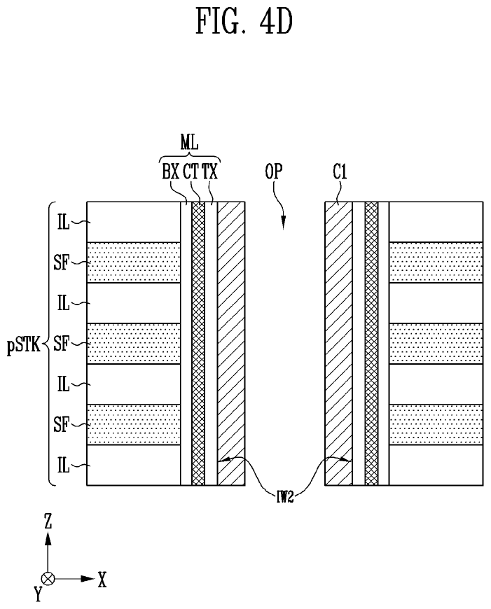

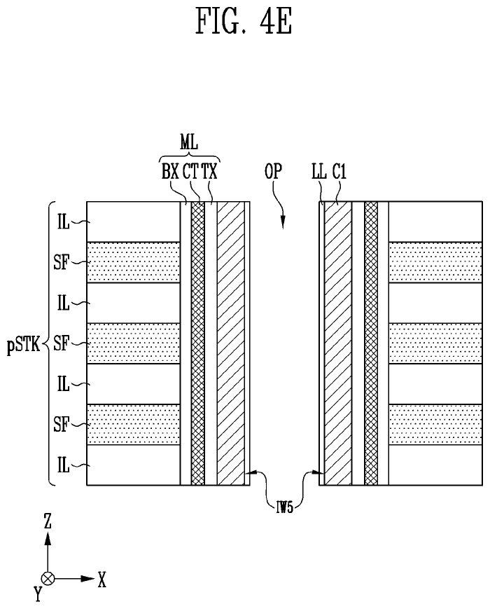

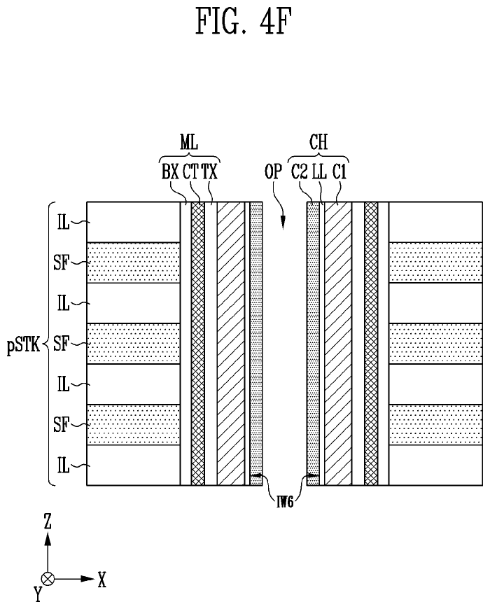

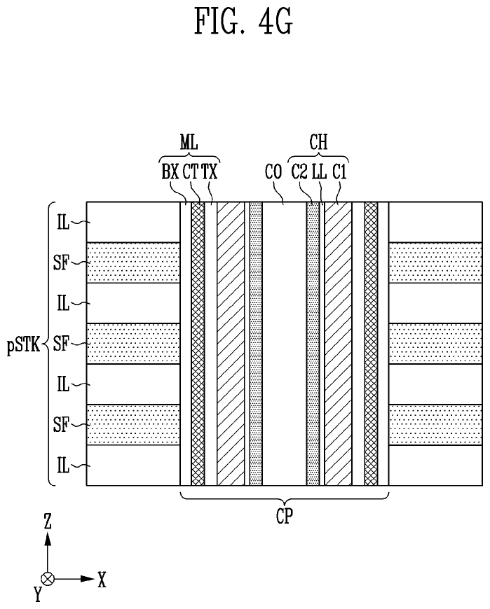

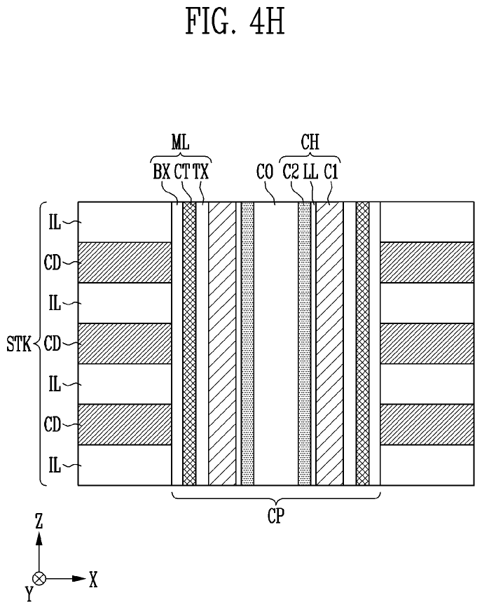

FIGS. 4A to 4H are views illustrating a manufacturing method of a memory device in accordance with an embodiment of the present disclosure.

Referring to FIG. 4A, a preliminary stack structure pSTK may be formed, in which first material layers SF and second material layers IL are alternately stacked. The first material layer SF may be formed of a material which can be selectively removed in a subsequent process. The second material layer IL may be formed of an insulating material. The first material layer SF may be formed of a material having an etch selectivity different from an etch selectivity of the second material layer IL. For example, the first material layer SF may be formed of a nitride layer. The second material layer IL may be an oxide layer (e.g., a silicon oxide layer).

Referring to FIG. 4B, an opening OP may be formed inside the preliminary stack structure pSTK. The opening OP may penetrate the first material layers SF and the second material layers IL, which are alternately stacked. The opening OP may have a cylindrical shape extending in the Z direction. An anisotropic dry etching process may be performed so as to form the opening OP at a specified position.

Referring to FIG. 4C, a memory layer ML may be formed along an inner wall IW1 of the opening OP. For example, a blocking layer BX may be formed along the inner wall IW1 of the opening OP, a charge trap layer CT may be formed along an inner wall IW3 of the blocking layer BX, and a tunnel insulating layer TX may be formed along an inner wall IW4 of the charge trap layer CT. The blocking layer BX and the tunnel insulating layer TX may be formed of an oxide layer (e.g., a silicon oxide), an oxynitride layer (e.g., a silicon oxynitride layer), or any combination thereof. The charge trap layer CT may be formed of a nitride layer or a variable resistance material.

Referring to FIG. 4D, a first sub-channel layer C1 may be formed in the opening OP. For example, the first sub-channel layer C1 may be formed along an inner wall IW2 of the memory layer ML. That is, the first sub-channel layer C1 may be formed on the inner wall IW2 of the memory layer ML.

The first sub-channel layer C1 may be formed of undoped silicon. The first sub-channel layer C1 may be formed through a process of depositing the undoped silicon on the inner wall IW2 of the memory layer ML.

Referring to FIG. 4E, a liner layer LL may be formed along an inner wall IW5 of the first sub-channel layer C1. That is, the liner layer LL may be 20 formed on the inner wall IW5 of the first sub-channel layer C1. The liner layer LL may be formed to have a thickness thinner than a thickness of the first sub-channel layer C1. The liner layer LL may be formed of an insulating layer. For example, the liner layer LL may be formed of an oxide layer. The liner layer LL may be formed through a process of depositing the insulating liner layer LL, on the inner wall IW5 of the first sub-channel layer C1.

Referring to FIG. 4F, a second sub-channel layer C2 may be formed along an inner wall IW6 of the liner layer LL. That is, the second sub-channel layer C2 may be formed on the inner wall IW6 of the liner layer LL. The second sub-channel layer C2 may be formed to have a thickness which is thinner than the thickness of the first sub-channel layer C1 and is thicker than the thickness of the liner layer LL.

The second sub-channel layer C2 may be formed of silicon doped with an impurity. The impurity may be a Group XIII element. For example, the impurity may be boron.

The second sub-channel layer C2 may be formed through a process of doping the impurity into a silicon layer formed on the inner wall IW6 of the liner layer LL. For example, the silicon layer may be formed along the inner wall IW6 of the liner layer LL. Subsequently, the impurity may be implanted into the silicon layer through the opening OP. For example, the impurity may be implanted into the silicon layer through a tilting ion implantation process. The tilting ion implantation process may be an ion implantation process in which an angle formed by a direction in which the impurity is implanted and a substrate is smaller than 90 degrees. The silicon layer into which the impurity is implanted may constitute the second sub-channel layer C2.

The first sub-channel layer C1, the liner layer LL, and the second sub-channel layer C2, which are formed in the opening OP, may constitute a channel layer CH. The channel layer CH may include the first sub-channel layer C1, the liner layer LL, and the second sub-channel layer C2, which are sequentially formed.

Referring to FIG. 4G, a pillar CO may be filled inside the second sub-channel layer C2. For example, the pillar CO may be filled in a region surrounded by the second sub-channel layer C2. The memory layer ML, the channel layer CH, and the pillar CO, which are formed in the opening OP, may constitute a cell plug CP. The pillar CO may be formed of an insulating layer or a conductive layer.

Referring to FIG. 4H, the first material layers SF may be replaced with third material layers CD, thereby forming a stack structure STK. For example, although not shown in FIG. 4H, trenches penetrating the preliminary stack structure pSTK may be formed. The first material layers SF exposed through the trenches may be removed. While the first material layers SF are removed, the cell plug CP filled in the opening OP may support the second material layers IL. The third material layers CD may be filled in regions in which the first material layers SF are removed, i.e., between the second material layers IL. The third material layers CD may be formed of at least one of tungsten (W), cobalt (Co), nickel (Ni), molybdenum (Mo), silicon (Si), and poly-silicon (poly-Si). Each of the third material layers CD may be used as a gate line, e.g., a drain select line, a word line, or a source select.

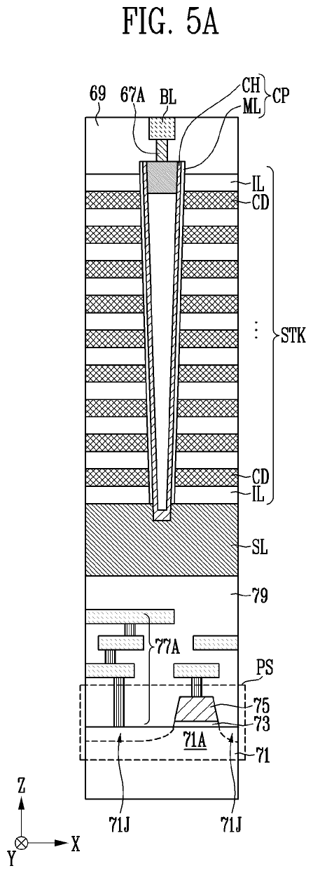

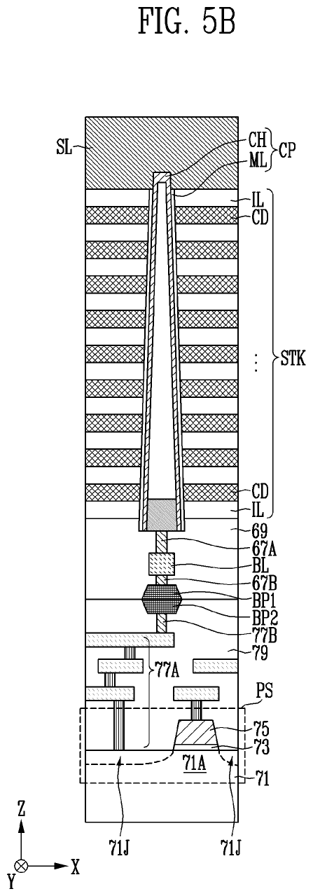

FIGS. 5A and 5B are views illustrating a section of a memory device including a cell plug in accordance with an embodiment of the present disclosure. FIGS. 5A and 5B may illustrate some of various embodiments in which the cell plug CP described in FIGS. 3A and 3B and 4A to 4H may be included in the memory device. However, FIGS. 5A and 5B correspond to some examples to which the present disclosure may be applied. Any memory device, even when it does not correspond to the embodiment shown in FIG. 5A or 5B, may be included in the scope of the present disclosure as long as it includes the channel layer CH described in FIGS. 3A and 3B and 4A to 4H.

Referring to FIGS. 5A and 5B, the memory device may include a stack structure STK including conductive layers CD and interlayer insulating layers IL, which are alternately stacked, and a cell plug CP inside the stack structure STK. The cell plug CP may include a channel layer CH and a memory layer ML between the channel layer CH and the stack structure STK. The channel layer CH may be used as a channel region of the string ST shown in FIG. 2. A partial region (e.g., a charge trap layer CT) of the memory layer ML may be used as a data storage region of the memory cells MC1 to MCj shown in FIG. 2.

The memory device may include a bit line BL connected to the cell plug CP. The cell plug CP may be connected to the bit line BL through a bit line contact 67A. The channel layer CH may be electrically connected to the bit line BL via the bit line contact 67A. The bit line contact 67A and the bit line BL may be disposed inside a first insulating structure 69.

The memory device may include a source line SL connected to the cell plug CP. An end portion of the channel layer CH may be connected to the source line SL. The source line SL may include at least one of an n-type impurity (e.g., a Group XV element) and a p-type impurity (e.g., a Group XIII element).

The memory device may include a semiconductor substrate 71, a peripheral circuit structure PS, a second insulating structure 79, and a plurality of interconnections 77A.

The peripheral circuit structure PS may include a region overlapping with the source line SL, the stack structure STK, and the bit line BL. The peripheral circuit structure PS may include a plurality of transistors, a capacitor, a resistor, and the like, which constitute the peripheral circuit 170 shown in FIG. 1. The peripheral circuit structure PS may be adjacent to the source line SL as shown in FIG. 5A, or be adjacent to the bit line BL as shown in FIG. 5B.

The semiconductor substrate 71 may include an active region 71A partitioned by an isolation layer (not shown). The peripheral circuit structure PS may include at least one transistor. The transistor may include a gate insulating layer 73 and a gate electrode 75, which are stacked on the active region 71A of the semiconductor substrate 71, and source/drain junctions 71J formed in the active region 71A at both sides of the gate electrode 75. The plurality of interconnections 77A may include sub-interconnections individually connected to the gate electrode 75 and the source/drain junctions 71J.

The semiconductor substrate 71 and the peripheral circuit structure PS may be covered with the second insulating structure 79, and the plurality of interconnections 77A may be disposed inside the second insulating structure 79.

Referring to FIG. 5A, processes of forming the source line SL, the stack structure STK, and the cell plug CP may be performed on the peripheral circuit structure PS. For example, after the source line SL is formed on the peripheral circuit structure PS, processes of forming the stack structure STK and the cell plug CP may be performed on the source line SL.

Referring to FIGS. 5B, a process of forming the peripheral circuit structure PS and processes of forming the source line SL, the stack structure STK, and the cell plug CP may be individually performed. The memory device may further include a first contact 67B and a first bonding pad BP1, which are disposed in the first insulating structure 69, and a second contact 77B and a second bonding pad BP2, which are disposed in the second insulating structure 79. The first bonding pad BP1 and the second bonding pad BP2 may be connected to each other through a bonding process. A process of forming the source line SL may be performed after the bonding process.

In addition to the structures shown in FIGS. 5A and 5B, memory devices having various structures may be included in the scope of the present disclosure as long as the channel layer CH included in the cell plug CP includes the first sub-channel layer C1, the liner layer LL, and the second sub-channel layer C2.

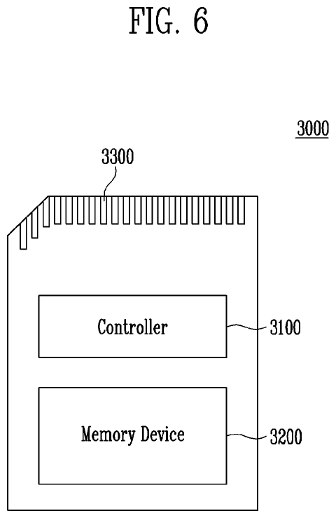

FIG. 6 is a diagram illustrating a memory card system to which the memory device of the present disclosure is applied.

Referring to FIG. 6, the memory card system 3000 includes a controller 3100, a memory device 3200, and a connector 3300.

The controller 3100 may be connected to the memory device 3200. The controller 3100 may access the memory device 3200. For example, the controller 3100 may control a program, read or ease operation, or control a background operation of the memory device 3200. The controller 3100 may provide an interface between the memory device 3200 and a host. The controller 3100 may drive firmware for controlling the memory device 3200. For example, the controller 3100 may include components such as a Random Access Memory (RAM), a processing unit, a host interface, a memory interface, and the error corrector.

The controller 3100 may communicate with an external device through the connector 3300. The controller 3100 may communicate with the external device (e.g., the host) according to a specific communication protocol. For example, the controller 3100 may communicate with the external device through at least one of various communication protocols such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), firewire, a Universal Flash Storage (UFS), Wi-Fi, Bluetooth, and NVMe. For example, the connector 3300 may be defined by at least one of the above-described various communication protocols.

The memory device 3200 may include memory cells, and be configured identically to the memory device 100 shown in FIG. 1.

The controller 3100 and the memory device 3200 may be integrated into a single semiconductor device, to constitute a memory card. For example, the controller 3100 and the memory device 3200 may constitute a memory card such as a personal computer (PC) card (Personal Computer Memory Card International Association (PCMCIA)), a Compact Flash (CF) card, a Smart Media Card (SM and SMC), a memory stick, a Multi-Media Card (MMC, RS-MMC, MMCmicro and eMMC), an SD card (SD, miniSD, microSD and SDHC), and a Universal Flash Storage (UFS).

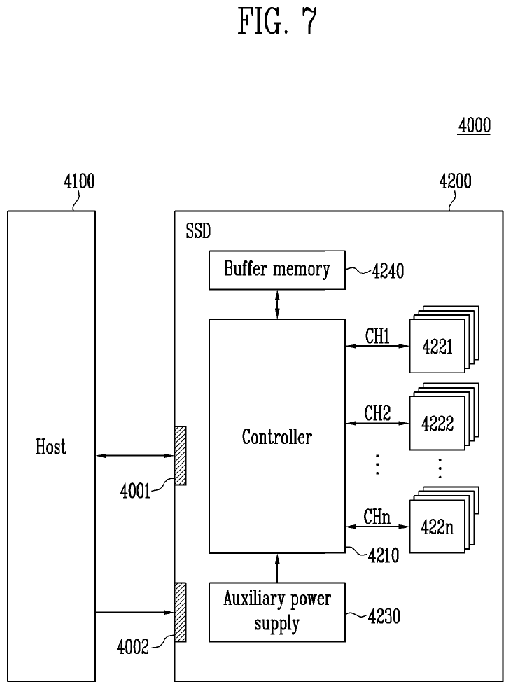

FIG. 7 is a diagram illustrating a Solid State Drive (SSD) system to which the memory device of the present disclosure is applied.

Referring to FIG. 7, the SSD system 4000 may include a host 4100 and an SSD 4200. The SSD 4200 may exchange a signal with the host 4100 through a signal connector 4001, and receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to a signal received from the host 4100. For example, the signal may be a signal based on an interface between the host 4100 and the SSD 4200. For example, the signal may be a signal defined by at least one of interfaces such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), a firewire, a Universal Flash Storage (UFS), a WI-FI, a Bluetooth, and an NVMe.

The plurality of memory devices 4221 to 422n may include a plurality of memory cells configured to store data. Each of the plurality of memory devices 4221 to 422n may be configured identically to the memory device 100 shown in FIG. 1. The plurality of memory devices 4221 to 422n may communicate with the controller 4210 through channels CH1 to CHn.

The auxiliary power supply 4230 may be connected to the host 4100 through the power connector 4002. The auxiliary power supply 4230 may receive power PWR input from the host 4100 and charge the power PWR. When the supply of power from the host 4100 is not smooth, the auxiliary power supply 4230 may provide power of the SSD 4200. For example, the auxiliary power supply 4230 may be located in the SSD 4200, or be located at the outside of the SSD 4200. For example, the auxiliary power supply 4230 may be located on a main board, and provide auxiliary power to the SSD 4200.

The buffer memory 4240 may operate as a buffer memory of the SSD 4200. For example, the buffer memory 4240 may temporarily store data received from the host 4100 or data received from the plurality of memory devices 4221 to 422n, or temporarily store meta data (e.g., a mapping table) of the memory devices 4221 to 422n. The buffer memory 4240 may include volatile memories such as a DRAM, an SDRAM, a DDR SDRAM, an LPDDR SDRAM, and a GRAM or nonvolatile memories such as a FRAM, a ReRAM, an STT-MRAM, and a PRAM.

In accordance with the present disclosure, the quantity of charge carriers included in a channel layer of a cell plug is increased, thereby improving the operational reliability, particularly, retention of the memory device.

While the present disclosure has been shown and described with reference to certain exemplary embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described exemplary embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the exemplary embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A memory device comprising:
a stack structure; and
a channel layer inside the stack structure,
wherein the channel layer includes:
a first sub-channel layer;
a liner layer formed along an inner wall of the first sub-channel layer; and
a second sub-channel layer formed along an inner wall of the liner layer.

2. The memory device of claim 1, wherein the first sub-channel layer includes an undoped silicon layer.

3. The memory device of claim 1, wherein the second sub-channel layer includes a silicon layer doped with an impurity.

4. The memory device of claim 3, wherein the impurity is a Group XIII element.

5. The memory device of claim 3, wherein the impurity is boron.

6. The memory device of claim 1, wherein the liner layer is an insulating layer.

7. The memory device of claim 1, wherein the first sub-channel layer has a first width, and
the second sub-channel layer has a second width less than the first width.

8. The memory device of claim 7, wherein the liner layer has a third width less than the second width.

9. The memory device of claim 1, wherein each of the first sub-channel layer, the second sub-channel layer, and the liner layer penetrates the stack structure.

10. The memory device of claim 1, wherein the liner layer is formed between the first sub-channel layer and the second sub-channel layer.

11. The memory device of claim 1, wherein the liner layer is formed along an outer wall of the second sub-channel layer.

12. The memory device of claim 1, further comprising a memory layer on an outer wall of the channel layer.

13. The memory device of claim 12, wherein the memory layer includes a blocking layer, a charge trap layer, and a tunnel insulating layer.

14. The memory device of claim 13, wherein the tunnel insulating layer surrounds a side surface of the first sub-channel layer,
the charge trap layer surrounds a side surface of the tunnel insulating layer, and
the blocking layer surrounds a side surface of the charge trap layer.

15. The memory device of claim 1, further comprising a pillar inside the channel layer.

16. The memory device of claim 1, wherein the stack structure includes conductive layers and interlayer insulating layers, which are alternately stacked.
